(19) United States
(12) Patent Application Publication
(10) Pub. No.: US 2012/0042933 A1
(43) Pub. Date: Feb. 23, 2012

(54) PHOTOVOLTAIC CONVERTER WITH INCREASED LIFETIME

(75) Inventors: Jean-Antoine Gruss, Seyssinet (FR); Claude Jaussaud, Meylan (FR); Olivier Poncelet, Grenoble (FR)

(73) Assignee: COMMISSARIAT A L'ENERGIE ATOMIQUE ET AUX ENE ALT, Paris (FR)

(21) Appl. No.: 13/146,081

(22) PCT Filed: Jan. 21, 2010
(86) PCT No.: PCT/EP2010/050672

§ 371 Date: Oct. 17, 2011

(30) Foreign Application Priority Data
Jan. 26, 2009 (FR) 09 50452

(51) Int. Cl. H01L 31/055; H01L 31/18

(52) U.S. Cl. 136/247; 438/72; 257/E31.119

(57) ABSTRACT

A photovoltaic conversion device including an area for collecting photons provided by luminous radiation and an area for converting the photons into electrical energy, the collecting area and the converting area being distinct, a fluid loaded with photoluminescent particles being for flowing between the collecting area and the converting area, the particles collecting photons and conveying them to the converting area in which they are reemitted.

### TECHNICAL FIELD AND PRIOR ART

The present invention relates to a photovoltaic conversion device with an increased lifetime.

Different types of photovoltaic cells can be used in a photovoltaic conversion device.

Some cells are made from monocrystalline silicon, polycrystalline silicon or amorphous silicon, and the cells can be solid or formed with thin layers.

Other cells are made of thin film by CIS (Copper Indium Selenium) or CdTe (Cadmium telluride) type depositing on glass or metal.

Still other cells are of the organic type deposited on glass or a flexible film.

Drawbacks are related to the manufacture and use of such cells.

In the case of silicon-based cells, cost thereof is relatively high due both to the cost of silicon and of the method for making them. It is possible to reduce the amount of silicon required for making one cell, by using a concentrator but the cost thereof is also high. Besides, polymeric materials are generally implemented in structuring silicon-based photovoltaic modules, but they are sensitive to ultraviolet radiation and humidity, therefore the lifetime of such devices is reduced.

The lifetime issue also appears in the case of organic cells, due to ultraviolet radiations and humidity.

Besides, the electromagnetic radiation to which the cells, and more generally the photovoltaic device, are subjected, also emits in infrared. Yet the cells are generally not capable of converting photons emitted in infrared. This radiation then only causes a heating of the device. This heating causes the conversion yield to decrease and may damage cells and reduce the lifetime thereof.

Besides, current photovoltaic conversion devices only produce electrical power when cells thereof receive a radiation. This means that in low sunshine periods, typically during night time, there is no electrical power generation. This is particularly a problem in the case of systems disposed in sites isolated and powered by a photovoltaic device. Means must therefore be provided for storing part of the electrical power generated during the sunshine period, such as lead secondary cells. Yet, this kind of secondary cell has a high purchase and maintenance cost. Besides, such secondary cells cause toxicity problems.

There are photovoltaic conversion devices also capable of valorising the heating caused by the infrared radiation, for example from U.S. Pat. No. 4,135,537. Such devices comprise a case provided with a face transparent to luminous rays and photovoltaic panels for converting the luminous radiations into electrical power. The case is coupled to a circuit provided with a heat exchanger, and a fluid loaded with luminescent particles flows in the case and in the heat exchanger to collect the heat collected by the fluid upon passing through the case.

This device is intended to cool the cells by circulating the fluid. However, the cells are still heated by the infrared radiation.

Besides, there is still the electrical power generation problem in low sunshine periods. Furthermore, the cells of U.S. Pat. No. 4,135,537 are directly subjected to ultraviolet radiation.

Consequently, one of the objects of the present invention is to provide a photovoltaic device with increased lifetime.

### DESCRIPTION OF THE INVENTION

The object set out above is achieved by a photovoltaic conversion device comprising a first area in which the luminous radiation is collected and a second area provided with photovoltaic cells for converting the luminous radiation into electrical power, the transfer from the collecting area to the converting area being carried out by means of photoluminescent particles.

Advantageously, using phosphorescent photoluminescent particles, the reemission of photons is made with some delay, with the result that the conversion into electrical power is deferred. Generating electrical power out of a sunshine period can then be contemplated.

Consequently, the photovoltaic cells are not directly subjected to the luminous radiation any more. As a result, the cells are not directly heated by the infrared radiation any more. Besides, the solar cells are not subjected to the ultraviolet radiation any more since photons reemitted by photoluminescent particles are in the visible spectrum. The lifetime of cells is thus increased.

There can also been provided means for recovering the heat conveyed by the fluid containing photoluminescent particles.

The subject-matter of the present invention is a photovoltaic conversion device comprising an area for collecting photons provided by the luminous radiation and an area for converting said photons into electrical energy, the collecting area and the converting area being formed by distinct enclosures, a fluid loaded with photoluminescent particles being for flowing between the collecting area and the converting area, said particles collecting photons and conveying them to the converting area in which they are reemitted.

Particularly advantageously, the photoluminescent particles are phosphorescent particles. These are for example sulphides or selenides or oxide type phosphors, and more particularly zinc sulphides or doped alkaline ferrous aluminates.

As for the fluid, it may be an alkane or perfluoroalkane.

A mass concentration of the photoluminescent particles is, for example, selected between 0.1% and 30%.

The fluid may also advantageously comprise nanoparticles enabling the “quantum cutting” phenomenon to occur and/or promoting wavelength conversion of the reemitted photons from ultraviolet to visible light.

More particularly, the enclosure of the collecting area may comprise at least one face transparent to luminous radiation and the enclosure of the photovoltaic conversion area may have a portion at least of the inner faces of its inner structures being covered with photovoltaic cells, each enclosure comprising a feeding port and a discharging port for the fluid, the discharging port of one enclosure being connected to the feeding port of the other enclosure.

Advantageously, the photovoltaic conversion device according to the invention can comprise a heat exchanger, which enables both the photovoltaic conversion yield to be increased by cooling the fluid before entering the converter, and the heat energy to be recovered.

In one embodiment, the converting area comprises at least a silicon plate in which are etched fluid flow channels, the materials of the plate and of the surface of the channels forming p-n junctions. In one exemplary embodiment, the channels are, for example, contained in the plane of the plate. In another exemplary embodiment, the channels are through channels and orthogonal to the plane of the plate so as to form a perforated membrane. Thus, inner structure means for example an assembly of plates.

The photovoltaic conversion device according to the invention can comprise a stack of at least two plates. The plates of the stack may be powered with the fluid in parallel.

Then, there can be provided to dispose a heat exchanger sandwiched between each pair of plates of the stack.

In another embodiment, the converting area comprises photovoltaic cells made of a thin film of organic polymer or CIS, CIGS or CdTe deposited on metal or glass.

In an exemplary embodiment, the device comprises channels bounded by the thin films.

In another exemplary embodiment, the thin film is wound around itself bounding a spiral-shaped channel.

The device advantageously comprises spacers between different windings of the film so as to maintain two windings of the film away from each other to provide the channel, the spacers either being fastened between the windings, or formed in the film by die-pressing or embossing thereof.

In one alternative embodiment, the photovoltaic conversion device according to the invention comprises two channels wound round each another formed by folding the thin film back on itself and by winding this folded back film, one of the channels being for flowing the fluid loaded with photoluminescent particles and the other channel being for flowing the heat transfer fluid.

The fluid flow is, for example, carried out through a thermosyphon effect or by means of an electrical pump directly powered by the electrical power generated by the photovoltaic cells.

There can be provided to dispose the heat exchanger between the collecting area and the converting area, upstream of the converting area.

The subject-matter of the present invention is also a method for manufacturing a photovoltaic conversion device according to the present invention, comprising the following steps of making the converting area:
etching channels in a substrate of p- or n-doped silicon,
making a n- or p-type doping of the inner face of the channels, thus forming n- or p-type emitting areas and p- or n-type collecting areas,
depositing electrodes onto the emitting and collecting areas,
annealing said structure thus formed.

The method can also comprise the step of depositing an antireflecting material before the step of depositing the electrodes.

It can also comprise the step of assembling several stacked plates by bonding or soldering.

The subject-matter of the present invention is also a method for manufacturing a photovoltaic conversion device according to the invention comprising the steps of:
making a film of organic polymer of CIS, CIGS or CdTe, for example by a “roll to roll” type continuous method,
winding the film round itself leaving a clearance between the different layers of the winding.

Advantageously, this method comprises the step of structuring the spacer film or placing spacer elements on the film prior to winding the film to form a relief enabling to ensure the clearance between the different windings.

In one alternative embodiment, the method for manufacturing a photovoltaic conversion device according to the invention comprises the step of folding the film back on itself prior to winding it to provide two channels wound round each another.

### BRIEF DESCRIPTION OF THE DRAWINGS

The present invention will be better understood on the basis of the following description and the attached drawings in which:

FIG. 1 is a schematic representation of a photovoltaic conversion system according to the present invention,

FIG. 2 is a detailed view of one exemplary embodiment of a silicon-based photovoltaic converter that may be implemented in the system of FIG. 1, the converter being provided with channels,

FIG. 3 is a side view of the converter of FIG. 2 formed with several layers,

FIG. 4 is a detailed view of another exemplary embodiment of a silicon-based photovoltaic converter that may be implemented in the system of FIG. 1, the converter having the form of a membrane,

FIG. 5 is a detailed view of one alternative converter of FIG. 4,

FIG. 6A is a top view of the converter of FIG. 4,

FIG. 6B is a side view of a converter comprising a plurality of membranes stacked according to FIG. 4,

FIG. 7 is a top view of another example of a thin film-based photovoltaic converter that can be implemented in the system of FIG. 1,

FIGS. 8A and 8B are views of an alternative converter of FIG. 7,

FIG. 9 is a perspective view of another exemplary embodiment of a thin film based converter that can be implemented in the system of FIG. 1,

FIG. 10 is a side view of one alternative converter of FIG. 9.

### DETAILED DESCRIPTION OF PARTICULAR EMBODIMENTS

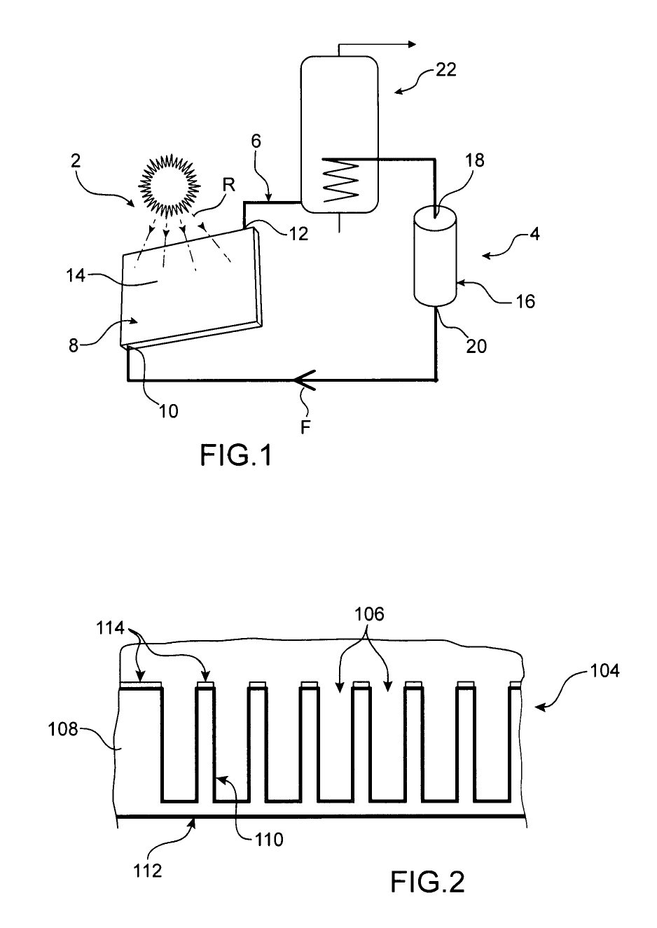

In FIG. 1 shows a schematic representation of a photovoltaic conversion system according to the present invention comprising a luminous radiation panel 2, a photovoltaic converter 4 separated from the panel 2 and a sealed circuit 6 for flowing the fluid between the panel 2 and the converter 4.

Throughout the description, the fluid flow is symbolised by the arrows F.

The luminous radiation panel 2 comprises an enclosure 8 bounding a space for containing a fluid, a fluid feeding inlet port 10 and a fluid discharging port 12 for enabling the fluid to flow through the inner space. At least one wall 14 of the enclosure 8 is transparent to the luminous radiation R enabling the fluid circulating in the enclosure to be exposed to the luminous radiation. In the represented example, the luminous radiation comes from the sun, but other sources are contemplated.

The photovoltaic converter also comprises an enclosure 16 bounding a space in which the fluid coming from the luminous radiation panel 2 flows. This enclosure 16 comprises, in a similar manner to the enclosure 8 of the luminous radiation panel 2, a fluid feeding port 18 and a fluid discharging port 20.

The enclosure 16 comprises on the inner faces of its walls that shall be called inner structures, photovoltaic cells (not shown) for collecting photons reemitted in all the directions of the space, as will be seen in the following description. The enclosure 16 need not to comprise a transparent outer wall, with the consequence that all of its walls can be covered with photovoltaic cells, which enables the collecting rate of reemitted photons to be increased, as will be seen in the following.

The discharging port 8 of the enclosure of the luminous radiation panel 2 is connected to the feeding port 16 of the enclosure of the photovoltaic converter 4, and the discharging port 18 of the enclosure of the photovoltaic converter is connected to the feeding port 12 of the luminous radiation panel 2.

Both enclosures may be disposed side by side or away from each other, in which case pipes are provided.

The fluid is loaded with suspended photoluminescent particles. The fluid may be a gas or a liquid. The carrier fluid is selected so as not to be an electrical conductor in order to avoid short-circuiting the electrodes. It can be for example a stable alkane or a perfluoroalkane.

Photoluminescent materials have the property to absorb photons in a wide electromagnetic radiation spectrum, they absorb both in visible spectrum and in ultraviolet spectrum, and reemit photons absorbed in the visible spectrum. Moreover, these materials reemit in all directions. As described above, since the enclosure 16 may comprise photovoltaic cells on all the inner faces of the inner structures thereof, photons reemitted in the three directions can be effectively collected.

The fluid flows in the system between the solar panel 2 and the photovoltaic converter 4, for example by means of a pump or by a thermosyphon effect.

In the example shown, the system also comprises a heat exchanger 22 mounted in the circuit 8 between the luminous radiation panel 2 and the photovoltaic converter, upstream of the converter in the flow direction of the fluid. This exchanger 22 is for taking in the heat conveyed by the fluid. In this advantageous example, recovering heat is further carried out. The energy efficiency of the system according to the invention is thus further increased. This disposition also enables the fluid to be cooled before entering the converter, therefore the heat effects on its yield and lifetime are limited.

This heat exchanger can be of the coil type flowing in a hot water tank and enabling to produce hot water for dwelling. There could also be provided to dispose this exchanger 22 between the photovoltaic converter and the luminous radiation panel 2.

The operation of the photovoltaic conversion system according to the present invention will now be explained.

The system is filled with a fluid loaded with photoluminescent particles, i.e. the enclosure 8 of the luminous radiation panel 2, the enclosure 16 of the photovoltaic converter and conduits connecting the panel 2 and the converter 4. The volume of fluid located in the panel 2 is exposed to luminous radiation. Photons the wavelength of which is in the visible and ultraviolet spectra are absorbed by photoluminescent particles at time t. The volume of fluid is further heated by the infrared radiation.

The volume of fluid flows in the circuit and joins the photovoltaic converter 4. Photoluminescent particles reemit at time t+x photons in the visible spectrum, such photons being collected by the photovoltaic cells located in the inner structures of the enclosure 16. As explained above, reemitted protons are reemitted in all the space directions, and the presence of cells on all the inner faces of the inner structures of the enclosure 16 enables collecting of photons to be optimised. Such photons are then converted into electrical power. The fluid can also be circulated permanently, regardless of the time elapsed between collecting photons and reemitting them.

It is worth to note that as the fluid moves continuously through the device, collecting photons by phosphorescent particles is made continuously, as well as their reemission. A continuous current generation is thus achieved.

Thanks to the invention, the converter 4 is not directly exposed to luminous radiation, on the other hand reemitted photons are so in the visible spectrum. Consequently, the converter and more particularly the photovoltaic modules are thus not exposed to ultraviolet radiation. Consequently, the lifetime of polymers used for making the converter is increased with respect to known type of converters. In the case of organic polymer photovoltaic cells, lifetime thereof is also increased, since they are also very sensitive to ultraviolet radiation.

Besides, since the photovoltaic converter 4 is not directly exposed to luminous radiation, it is not exposed to infrared radiation. The heating of the cells is thus limited and is only due to the heating of the fluid itself upon exposing to luminous radiation.

The cell yield is therefore not penalized. More over, by providing a heat exchanger upstream of the converter 4, the fluid temperature is further decreased, prior to entering the converter 4.

Particularly advantageously, there is provided using phosphorescent particles as the photoluminescent particles.

Phosphorescence is a particular type of photoluminescence in which the reemission phenomenon is temporally deferred. Absorbed photons pass through intermediate energy states, typically triplet states (forbidden), the unavoidable return of trapped photons from these forbidden states to a low energy level is kinetically hindered, which results in slowing down the luminous emission, consequently the reemission of the absorbed energy for most phosphorescent materials is in the order of one millisecond. It is possible to have triplet states the lifetime of which is several hours, which implies a reemission of photons several hours after absorption thereof.

This “deferred” reemission has the advantage of providing electrical power generation in the absence of luminous radiation. Indeed, photons “captured” by phosphorescent particles during a sunshine period, typically during daytime, are reemitted during night time in the converter which then generates electrical power, in particular in the case of a reemission “deferred” from several hours.

The converter can be operated permanently, using the strong afterglow of phosphorescent materials, photons being reemitted up to 12 hours after exposition thereof. Accordingly, this enables, in the case where a substantially constant electrical power supply is required 24 hours a day, to reduce the capacity of storing batteries, or even to remove them.

There can be provided to permanently circulate the fluid in the circuit. When an electrical pump is used, the electrical power required to drive this pump can be directly that generated by the conversion system according to the present invention.

Also advantageously, there can be provided to add in the fluid nanoparticles enabling the “quantum cutting” phenomenon to occur in order to increase the cell yield. “Quantum cutting” is a mechanism enabling, from one photon emitting in ultraviolet, to give two photons emitting in the visible light or in a spectrum close to infrared. The theoretical yield of one cell can thus be changed from 30% to 40%.

Phosphorescent particles convert high energy photons (UV) into low energy photons (visible) by deferring this reemission in time.

In the case of phosphorescent particles, the lifetime of such triplet states can exceed several hours. Since these phenomena are “slow”, there is only little luminescent quenching, so that the excitation field is more “effective”.

By way of example, there can be selected as phosphorescent materials, sulphides or selenides such as cadmium sulphides or alkaline-earth sulfoselenides or sulphides, sulfoselenides, oxisulphides.

There can also be selected particles from oxide type phosphor family such as aluminates, gallates, silicates and germanates, halophosphates and phosphates, arsenates, vanadates, niobiates, tantalates, sulphates, tungstates, molybdates, as well as from metal halide type phosphors.

Such materials have the advantage to absorb both in infrared and in ultraviolet and to reemit in visible light, in red or green.

Particularly advantageously, it can be selected zinc sulphides or alkaline-earth (Sr) aluminates doped with rare earths. The latter enable the emission field of fluorescent photons to be controlled, which enables to adapt the photon emission depending on the emission band in which the converter is the most effective.

Inorganic phosphorescent materials can also be used, advantageously having higher quantum yields and being little sensitive to heat.

The particle size is advantageously between 0.1 μm and 1 μm, with a concentration, for example, between 0.1% and 30% mass.

Different exemplary embodiments of photovoltaic converters that can be used in the photovoltaic conversion system according to the present invention will now be described.

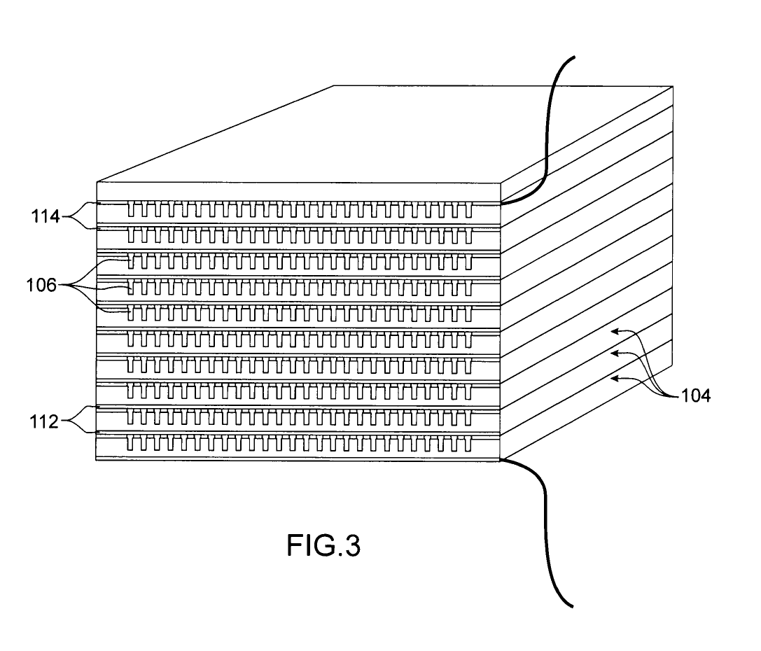

FIGS. 2 and 3 show an exemplary embodiment of a photovoltaic converter 104 enabling an optimised collection of photons emitted in the three dimensions.

This converter comprises channels 106 etched in a plate-shaped silicon substrate 108, the channels being contained in the plane of the plate. The fluid is intended to flow in the channels a first longitudinal end of which is connected to the feeding port of the enclosure of the converter and a second end of which is connected to the discharging port of the enclosure of the converter. The fluid is thus intended to flow in the plane of the plate.

In the example shown, the substrate 108 in which are etched the channels 106 is n-doped, and then a deposition of p-doped silicon 110 is carried out onto the substrate 108, the p-doped silicon covering the inside of channels. p-n junctions are thus provided which, when bombarded by photons reemitted by the particles conveyed by the fluid flowing in the channels, will generate electrical power in a manner known to those skilled in the art.

A first electrode 112 is deposited on a back face of the plate in contact with the n-doped substrate, and a second electrode 114 is deposited on a front face of the plate in contact with the p-doped silicon layer, this face being in particular formed from the top of channels.

FIG. 3 shows a photovoltaic converter 116 formed by a stack of basis converters 104 similar to the plate shown in FIG. 2. This converter has the advantage to provide a very high collecting area of photons reemitted by the fluid.

In the example shown, the plates are electrically connected in series. Advantageously, these connections are simply achieved by directly contacting a positive electrode of one plate with a negative electrode of the next plate. The connection to the user device or the storing device is then simply made by the end electrodes of the device. The number of connections is thus dramatically reduced. A parallel connection of the converter plates can of course be performed.

In this exemplary embodiment, the different converter plates could be simultaneously fed by fluid coming from the radiation panel, or the fluid could be circulated in series from plate to plate thanks to fluid dispensers integral with the plates in order to collect the maximal amount of photons.

Feeding and discharging the fluid are for example performed by two vertical spurs, orthogonal to the plane of the plates.

In the example shown, the channels of the different plates are mutually orthogonal. Nevertheless, the channels could cross one another so that channels from a plate are orthogonal to channels from the higher and lower plates, the feeding of plates being crossed.

The heat exchanger could also be directly integrated within the converter, the latter being provided between each pair of plates, the heat being removed while the reemitted photons are converted by the photovoltaic cells.

A method for manufacturing a converter of the type represented in FIGS. 2 and 3 will now be described.

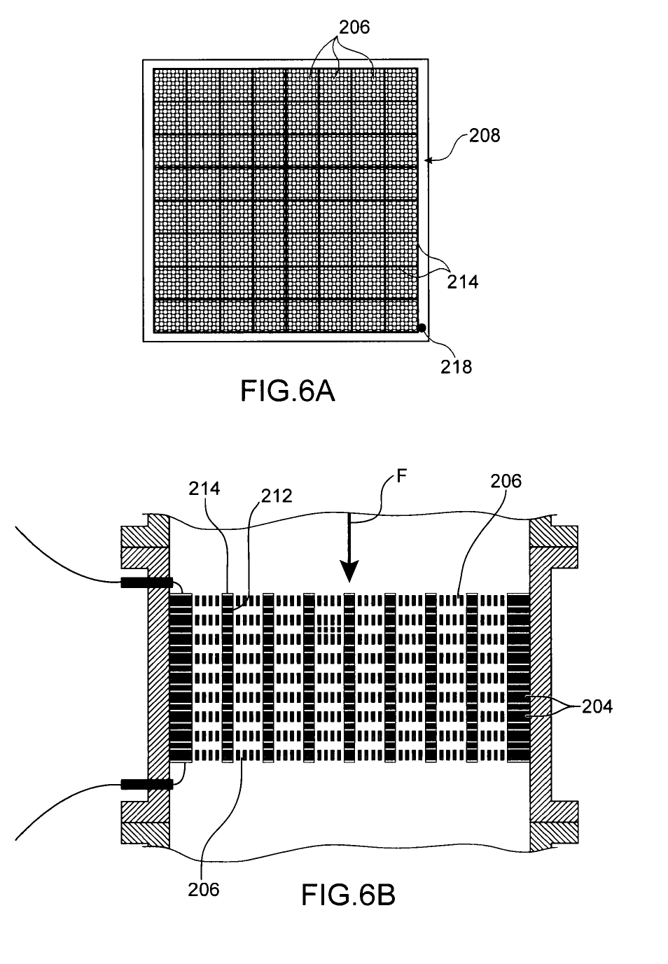

The method comprises the following steps:
etching the channels 106 in a p- (or n-) doped silicon substrate 108 using a known technique, such as mechanical sawing, dry or wet etching, such as for example KOH, TMAH, RIE etching, laser etching, electrochemical etching or any other etching method known to those skilled in the art;
then performing a n- (or p-) doping of the channels 106 and on the top of the substrate 108, the p-n junctions are thus formed. In one alternative embodiment, the emitter could be made by depositing doped amorphous silicon;
then performing a depositing a layer of antireflecting material, such as silicon nitride, or TCO (transparent conducting oxide) in the case of thin film cells;
then depositing the metal electrodes 112, 114. The electrode 112 on the n-type emitter is for example of silver, and the electrode 114 on the p-type collector is for example of aluminium;
it could be contemplated not to deposit electrodes on the top of channels and to limit the depositing to channel-free areas. In this case, channel-free areas are periodically made in order to effectively collect current, in a manner similar to the electrode 214 in FIG. 6A;
then performing an annealing at 850° C. of the structure thus made.

In the case where a structure similar to that of FIG. 3 is made, the different plates are stacked and assembled for example by bonding or soldering, and so on. As explained above, the plates are electrically mutually connected by direct contacting of the electrodes of consecutive plates, the assembly thus enables the cells to be electrically connected with each other in a simple manner.

By way of example, a substrate may be used the thickness of which is between 250 μm and 1000 μm, advantageously may be equal to 600 μm. The channels have a depth of 500 μm and a width between 50 μm and 500 μm, advantageously of 50 μm.

The width of partition walls between the channels is between 10 μm and 500 μm, and is advantageously equal to 20 μm.

The thickness of the n- (or p-) doped silicon layer is typically 500 nm.

The electrodes 112, 114 have a thickness of 10 μm.

In the case of an electrode 114 not covering the tops of channels, and where channel-free areas are periodically made, the latter may be typically made every 5 mm.

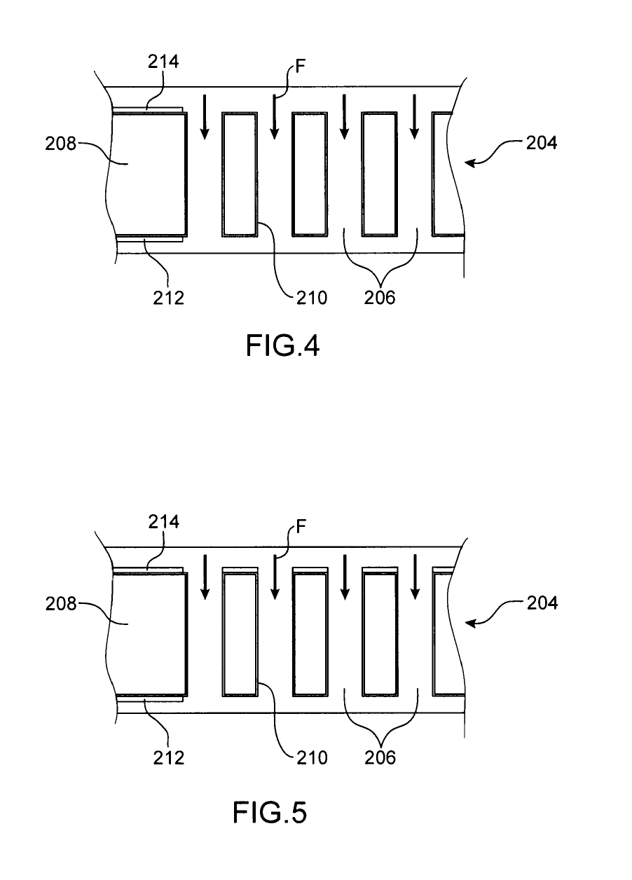

FIGS. 4 to 6B show another exemplary embodiment of the photovoltaic converter 204 according to the present invention.

The converter also comprises channels 206 made in a silicon substrate 208, however, unlike the channels of the converter of FIG. 2, these are made so that the fluid flow occurs in a direction orthogonal to a plane of the substrate, symbolised by the arrows 216.

The channels 206 are thus etched in the substrate so as to form through channels with an axis substantially orthogonal to the plane of the substrate 208. It is to be well understood that channels with an axis tilted with respect to the plane of the substrate do no depart from the scope of the present invention.

In the example shown, the substrate 208 in which are etched the channels 206 is n-doped, and then a depositing of p-doped silicon 210 is performed on the substrate 208, the p-doped silicon covering the inside of channels.

Then, the depositing of electrodes 212 and 214 onto the front and back faces of the substrate is performed.

The electrodes may only be deposited onto the edges of the plate (FIG. 4), or on the entire surface of the back face and the front face, which makes it easier to collect electrons.

The converter then forms a membrane pierced with many channels, intended for the fluid to flow through.

FIG. 6A shows a top view of a converter of FIG. 4 with the electrode 214 hatching the membrane surface. The connection of the electrode by means of electron collecting means is denoted by reference 218.

FIG. 6B shows a converter formed by a stack of membranes similar to that of FIG. 4 or 5. In a manner similar to the stack of FIG. 3, the membranes are electrically connected in series and two connections only to the collecting means are required.

In this photovoltaic converter, the flow is performed from one end to the another end of the converter. The photoluminescent fluid consecutively passes though the different membranes and the reemitted photons are collected.

The method for manufacturing the converter of FIGS. 4 and 5 is very similar to that of FIGS. 2 and 3. It differs therefrom by etching through channels and not channels contained in the plane of the substrate, however the etching means being used are similar to those used for the converter of FIGS. 2 and 3.

The channels have for example a diameter between 20 μm and 100 μm, being advantageously of 50 μm.

In the case of the structure of FIG. 6A, the channel-free areas are for example performed every 5 mm.

In the case of making the stack such as that of FIG. 6B, the assembly can be made by molecular adhesion, bonding or soldering.

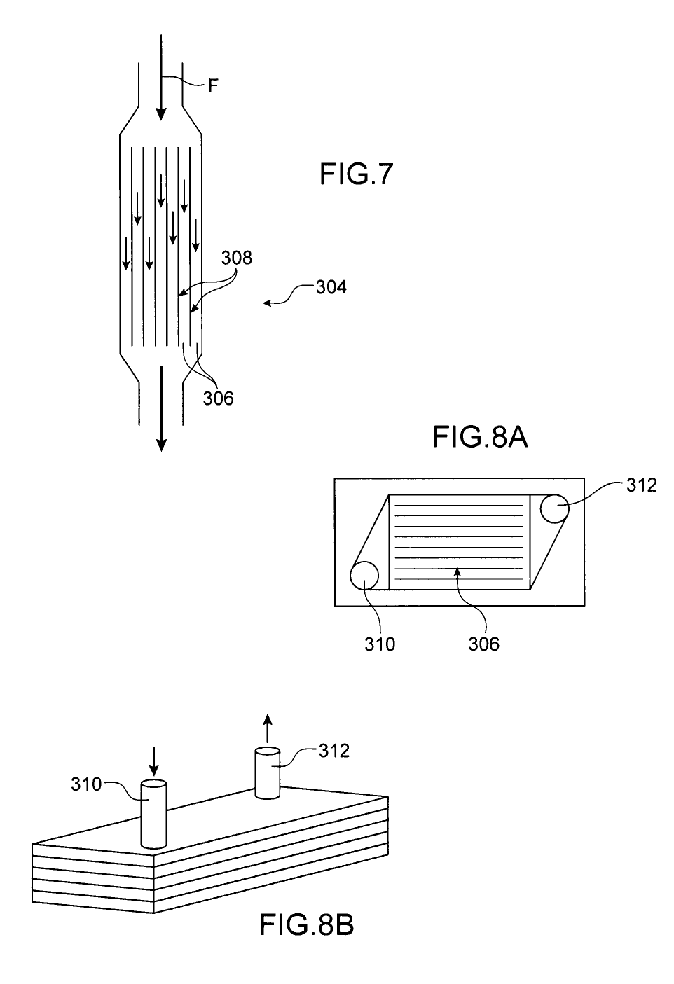

FIG. 7 shows an exemplary embodiment of the photovoltaic converter 304 according to the invention, wherein the photovoltaic cells are made from thin films, for example of organic polymer or CIS, CIGS or CdTe thin film.

In this example, the channels 306 are bounded inside the enclosure directly by thin films 308 forming the photovoltaic cells, provided in parallel to one another.

FIGS. 8A and 8B show an exemplary connection of this type of converter to the circuit. Two tips 310, 312 are provided on an upper face of the enclosure at two opposite vertices, the one providing fluid feeding, the other providing fluid discharging.

The electron collection on the film is conventionally made using deposited metal electrodes.

A method for manufacturing such a converter will now be described.

The films of cells made of organic polymer are manufactured in a conventional manner. For example, the films are preferentially made continuously by the so-called “roll to roll” technique.

Then, the films are assembled by bonding, making electrical connections of cells to one another, which enables the required series/parallel links to be made.

In the case of films, for example of CIGS or CIS, they are deposited onto a polymer or a metal.

The technique used for manufacturing CIS or CIGS films is also preferentially of the continuous “roll to roll” type.

The films may be assembled by bonding, by welding . . . by making the electrical connection of cells to one another enabling to make the required series/parallel links.

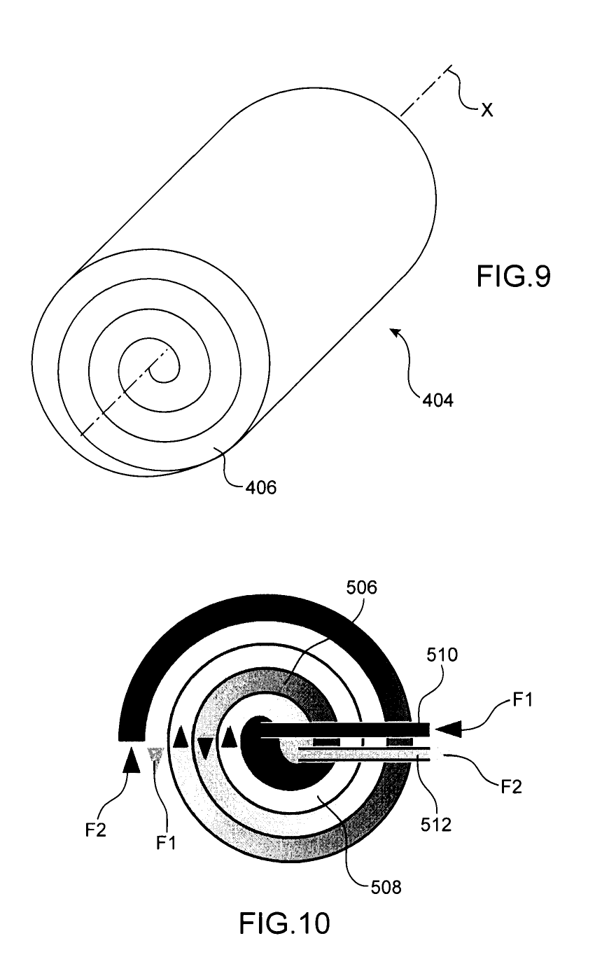

FIGS. 9 and 10 show two other exemplary embodiments 404, 504 of a photovoltaic converter made from a thin film wound round itself.

In FIG. 9, the converter comprises a channel 406 provided between the different layers of the winding for enabling the fluid flow. Such channel 406 can be obtained either by using spacers (not shown) sandwiched between the different layers of the winding, or by a direct structuration of the thin film, for example by die-pressing. The relief thus obtained determines the clearance between layers.

The flow can occur either along the winding axis X, or in the winding direction. In the latter case, means are provided to bring the fluid or discharge it at the winding axis X.

In the case of FIG. 10, the converter 504 is formed by a double winding forming two channels 506, 508 wound into one another, enabling to simultaneously circulate two fluids F1 and F2 in the winding. Advantageously, one F1 of the fluids is the fluid loaded with the photoluminescent particles and the other fluid F2 is a heat transfer fluid for removing heat from the photoluminescent fluid. Consequently, the converter also forms the heat exchanger. For that purpose, a thin film folded and then wound round itself is used.

At the winding axis X, the photoluminescent fluid F1 feed 510 and the heat transfer fluid F2 discharge 512 are provided. Advantageously, the fluids F1 and F2 are circulated in a back flow manner which improves the efficiency of heat exchanges.

In a manner similar to the converter of FIG. 9, thin films can advantageously be provided with a surface development by making channels obtained through different methods, such as etching, embossing, die-pressing or any other method.

Conduits formed by photovoltaic cells could also be provided, that is the converter could be integrated into the fluid flow pipeline.

The present invention is particularly interesting as an explosion-proof system, used in areas where all electrical power supplies should be avoided, such as in explosive areas.

1-27. (canceled)

28. A photovoltaic conversion device comprising:
an area for collecting photons provided by luminous radiation and an area for converting the photons into electrical energy, the collecting area and the converting area being formed by distinct enclosures; and
a fluid loaded with photoluminescent particles for flowing between the collecting area and the converting area, the particles collecting photons and conveying them to the converting area in which they are reemitted.

29. The photovoltaic conversion device according to claim 28, wherein the photoluminescent particles are phosphorescent particles.

30. The photovoltaic conversion device according to claim 29, wherein the phosphorescent particles are sulphides or selenides or oxide type phosphors.

31. The photovoltaic conversion device according to claim 30, wherein the phosphorescent particles are zinc sulphides or doped alkaline ferrous aluminates.

32. The photovoltaic conversion device according to claim 28, wherein mass concentration of the phosphorescent particles is between 0.1% and 30%.

33. The photovoltaic conversion device according to claim 28, wherein the fluid is an alkane or a perfluoroalkane.

34. The photovoltaic conversion device according to claim 28, wherein the fluid also comprises nanoparticles enabling a quantum cutting phenomenon to occur and/or promoting a wavelength conversion of the reemitted photons from ultraviolet to visible light.

35. The photovoltaic conversion device according to claim 28, wherein an enclosure of the collecting area comprises at least one face transparent to luminous radiation and an enclosure of the photovoltaic conversion area includes a portion at least of inner faces of its inner structures being covered with photovoltaic cells, each enclosure comprising a feeding port and a discharging port for the fluid, the discharging port of one enclosure being connected to the feeding port of the other enclosure.

36. The photovoltaic conversion device according to claim 28, further comprising a heat exchanger.

37. The photovoltaic conversion device according to claim 28, wherein the converting area comprises at least a plate wherein fluid flow channels are etched, materials of the plate and of a surface of the channels forming p-n or n-p junctions.

38. The photovoltaic conversion device according to claim 37, wherein the channels are contained in the plane of the plate.

39. The photovoltaic conversion device according to claim 37, wherein the channels are through channels and orthogonal to the plane of the plate so as to form a perforated membrane.

40. The photovoltaic conversion device according to claim 37, further comprising a stack of at least two plates.

41. The photovoltaic conversion device according to claim 40, wherein the plates of the stack are fed with the fluid in parallel.

42. The photovoltaic conversion device according to claim 40, wherein a heat exchanger is sandwiched between each pair of plates of the stack.

43. The photovoltaic conversion device according to claim 28, wherein the converting area comprises photovoltaic cells made of a thin film of organic polymers or CIS, CIGS or CdTe deposited on metal or glass.

44. The photovoltaic conversion device according to claim 43, further comprising channels bounded by the thin films.

45. The photovoltaic conversion device according to claim 43, wherein the thin film is wound around itself bounding a spiral-shaped channel.

46. The photovoltaic conversion device according to claim 45, further comprising spacers between different windings of the film so as to maintain two windings of the film away from each other to provide the channel, the spacers either being fastened between the windings, or formed in the film by die-pressing or embossing thereof.

47. The photovoltaic conversion device according to claim 45, further comprising two channels wound round one another formed by folding the thin film back on itself and by winding the folded back film, one of the channels being for a flow of the fluid loaded with photoluminescent particles and the other channel being for a flow of the heat transfer fluid.

48. The photovoltaic conversion device according to claim 28, further comprising a heat exchanger located between the collecting area and the converting area, upstream of the converting area.

49. A method for manufacturing a photovoltaic conversion device according to claim 37, comprising, for making the conversion area:
etching channels in a substrate of p- or n-doped silicon;
making a n-type or p-type doping of an inner face of the channels, thus forming n-type or p-type emitting areas and p-type or n-type collecting areas;
depositing electrodes onto the emitting and collecting areas; and
annealing the structure thus formed.

50. The method for manufacturing a photovoltaic conversion device according to claim 49, further comprising depositing an antireflecting material before depositing the electrodes.

51. The method for manufacturing a photovoltaic conversion device according to claim 49, further comprising assembling plural stacked plates by bonding or soldering.

52. The method for manufacturing a photovoltaic conversion device according to claim 43, further comprising:
making a film of organic polymer of CIS, CIGS or CdTe, or by a roll to roll type continuous method; and
winding the film round itself leaving a clearance between the different layers of the winding.

53. The method for manufacturing a photovoltaic conversion device according to claim 52, further comprising structuring the spacer film or placing spacer elements on the film prior to winding the film to form a relief enabling to ensure the clearance between the different windings.

54. The method for manufacturing a photovoltaic conversion device according to claim 52, further comprising folding the film back on itself prior to winding it to provide two channels wound round each another.
